(19) United States
(12) Patent Application Publication
(10) Pub. No.: US 2026/0324150 A1
(43) Pub. Date: Oct. 15, 2026

(54) LIGHT-EMITTING DEVICE AND MANUFACTURING METHOD THEREOF

(71) Applicant: EVERLIGHT ELECTRONICS CO., LTD., New Taipei City (TW)

(72) Inventors: Jen-Hsiung LAI, New Taipei City (TW); Bo Cheng JIANG, New Taipei City (TW)

(21) Appl. No.: 19/176,196

(22) Filed: Apr. 11, 2025

(51) Int. Cl. H10H 20/855; H10H 20/01; H10H 20/854

(52) U.S. Cl. CPC H10H 20/855; H10H 20/0362; H10H 20/0363; H10H 20/854

(57) ABSTRACT

The present disclosure provides a light-emitting device and a manufacturing method thereof. The light-emitting device includes a substrate, a light source, and an optical lens. The substrate has a main surface. The light source is disposed on the main surface and has a light-emitting surface away from the main surface. The optical lens is disposed on the main surface and covers the light source, in which the optical lens has an outer surface away from the light source and an indentation located on the outer surface and above the light-emitting surface.

### BACKGROUND

### Field of Invention

The present disclosure relates to a light-emitting device and a manufacturing method thereof.

### Description of Related Art

With the advancement of semiconductor technology, today's light-emitting diodes (LEDs) can provide high-brightness output. Since LEDs have the advantages of being power-saving, small in size, low-voltage driven, and mercury-free, they have been widely used in the fields of displays and lighting.

The LEDs usually have strong luminous directivity. Therefore, when the LEDs are used for backlighting, the backlighting may have the problem of uneven light distribution. Furthermore, when a diffuser is used to scatter the light of the LEDs, it is not easy to satisfy the requirements of making the light uniform and thinning the structure thickness simultaneously.

Accordingly, how to propose a light-emitting device that can solve the above problems is one of the problems that the industry is eager to solve.

### SUMMARY

The present disclosure provides a light-emitting device including a substrate, a light source, and an optical lens. The substrate has a main surface. The light source is disposed on the main surface and has a light-emitting surface away from the main surface. The optical lens is disposed on the main surface and covers the light source, in which the optical lens has an outer surface away from the light source and an indentation located on the outer surface and above the light-emitting surface.

In some embodiments, the outer surface has a convex curved surface, and the indentation has a concave curved surface.

In some embodiments, a distance between a bottom of the indentation and the light-emitting surface is from 0 mm to 19.9 mm.

In some embodiments, the optical lens has a first diameter, an opening of the indentation has a second diameter, and a ratio of first diameter to the second diameter is 1.3:1 to 2:1.

In some embodiments, the optical lens includes silicone, epoxy, poly(methyl methacrylate), thixotropic gel, or combinations thereof.

In some embodiments, the indentation has a depth from 0.05 mm to 19.9 mm.

In some embodiments, in a cross-section of the light-emitting device, the light-emitting surface has a first endpoint and a second endpoint, the first endpoint and a first opening edge of the indentation define a first virtual line, the second endpoint and a second opening edge of the indentation define a second virtual line, and an angle between the first virtual line and the second virtual line is greater than 0 degree and less than or equal to 160 degrees.

In some embodiments, the light-emitting device further includes at least one light-shielding wall disposed on the main surface and near the optical lens, in which the optical lens has a first height, the light-shielding wall has a second height, and the second height is less than or equal to two times the first height.

In some embodiments, the light-emitting device further includes a light-shielding material in the indentation.

In some embodiments, the light-shielding material has a transmittance of less than 80% for light with a wavelength of 360 nm to 1000 nm.

In some embodiments, the light-shielding material fills the indentation and protrudes out of the indentation.

In some embodiments, the light-shielding material includes an encapsulant and a pigment powder dispersed in the encapsulant.

The present disclosure provides a method of manufacturing a light-emitting device, and the method includes the following operations. A light source is disposed on a substrate. A dispensing machine is placed above the light source, in which the dispensing machine includes a dispensing nozzle and a firing pin disposed in a flow channel of the dispensing nozzle. An encapsulating layer is dispensed on the light source by extruding an encapsulant from the flow channel through pushing the firing pin with a dispensing pressure to strike an inner surface of the flow channel, in which the encapsulating layer has an indentation facing the dispensing nozzle. The encapsulating layer is cured to form an optical lens.

In some embodiments, the encapsulant has a viscosity between 0.2 mPa·s and 100000 mPa-s.

In some embodiments, a time for the firing pin striking the inner surface is 0.01 ms to 500 ms, and the dispensing pressure is 1 bar to 10 bar.

In some embodiments, curing the encapsulating layer includes the following operations. The encapsulating layer is heated under a first temperature from 40 ° C to 60 ° C The encapsulating layer is heated under a second temperature from 80 ° C to 100 ° C The encapsulating layer is heated at a third temperature from 110 ° C to 130 ° C.

In some embodiments, the encapsulant includes silicone, epoxy, poly(methyl methacrylate), thixotropic gel, or combinations thereof.

In some embodiments, the method further includes forming a light-shielding material in the indentation.

In some embodiments, the light-shielding material fills the indentation and protrudes out of the indentation.

In some embodiments, forming the light-shielding material in the indentation includes the following operations. An encapsulant material and a pigment powder are dispensed in the indentation, in which the pigment powder is dispersed in the encapsulant material. The encapsulant material and the pigment powder are heated under a first temperature from 40 ° C to 60 ° C The encapsulant material and the pigment powder are heated under a second temperature from 80 ° C and 100 ° C The encapsulant material and the pigment powder are heated under a third temperature from 110 ° C and 130 ° C.

### BRIEF DESCRIPTION OF THE DRAWINGS

The present disclosure can be more fully understood by reading the following detailed description of the embodiments, with reference made to the accompanying drawings.

FIG. 1 shows a luminous intensity distribution curve generated by a light-emitting diode embedded in a conventional optical lens between the luminous angle of −90 degrees and 90 degrees according to a comparative example of the present disclosure.

FIG. 2 is a flowchart of a method of manufacturing a light-emitting device according to various embodiments of the present disclosure.

FIG. 3A shows schematic views illustrating intermediate stages of manufacturing light-emitting devices according to various embodiments of the present disclosure.

FIG. 3B shows schematic cross-sectional views illustrating intermediate stages of forming an encapsulating layer on a light source by a dispensing machine according to various embodiments of the present disclosure.

FIG. 4A, FIG. 4B, and FIG. 5 are respectively schematic cross-sectional views of light-emitting devices according to various embodiments of the present disclosure.

FIG. 6 shows a luminous intensity distribution curve generated by the light-emitting device of FIG. 4A between the luminous angle of −90 degrees and 90 degrees.

FIG. 7 shows a luminous intensity distribution curve generated by the light-emitting device of FIG. 5 between the luminous angle of −90 degrees and 90 degrees.

FIG. 8, FIG. 9, FIG. 10, FIG. 11, FIG. 12, and FIG. 13 are respectively schematic cross-sectional views of light-emitting devices according to various embodiments of the present disclosure.

FIG. 14 illustrates luminous intensity change curves generated by the light-emitting devices of Examples 1-3 between the luminous angle of −90 degrees and 90 degrees at the longitudinal plane of 0 degree.

FIG. 15 illustrates luminous intensity change curves generated by the light-emitting devices of Examples 1-3 between the luminous angle of −90 degrees and 90 degrees at the longitudinal plane of 90 degrees.

### DETAILED DESCRIPTION

Reference will now be made in detail to the embodiments of the present disclosure, examples of which are illustrated in the accompanying drawings. Wherever possible, the same reference numbers are used in the drawings and the description to refer to the same or like parts.

The following embodiments are disclosed with accompanying diagrams for detailed description. For illustration clarity, many details of practice are explained in the following descriptions. However, it should be understood that these details of practice do not intend to limit the present disclosure. That is, these details of practice are not necessary in parts of embodiments of the present disclosure. Furthermore, for simplifying the drawings, some of the conventional structures and elements are shown with schematic illustrations.

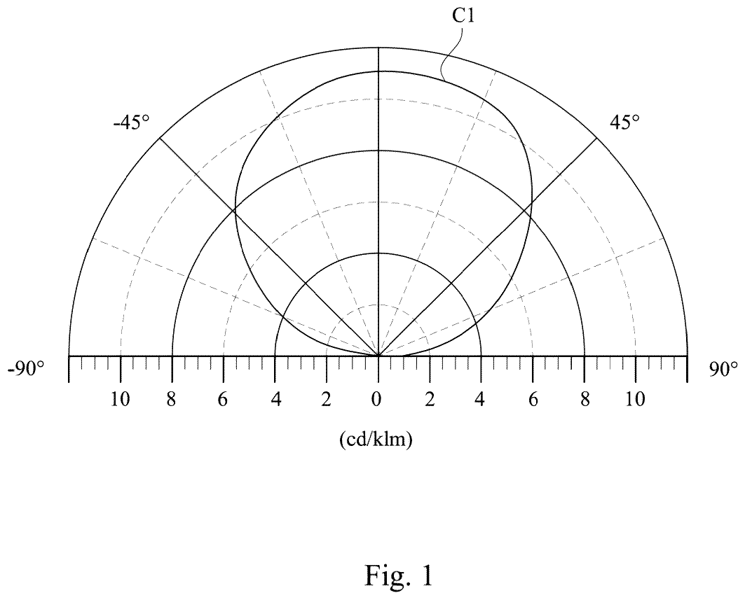

LEDs usually have strong luminous directivity. Therefore, when the LEDs are used in the fields of displays and lighting, the strong luminous directivity may cause the problem of uneven light distribution. For example, FIG. 1 shows a luminous intensity distribution curve C1 generated by a light-emitting diode embedded in a conventional optical lens between the luminous angle of −90 degrees and 90 degrees according to a comparative example of the present disclosure, in which the conventional optical lens is a plano-convex lens. The radial coordinate represents the luminous intensity, and the angular coordinate represents the luminous angle. The luminous intensity can also be referred to as a light intensity. As shown in FIG. 1, the luminous intensity distribution curve C1 is narrow, which means that most of the light is emitted from the center part of the convex surface of the conventional optical lens. When the light-emitting diode is used in a display device, the display device may have uneven light emission.

The present disclosure provides a light-emitting device and a manufacturing method thereof to overcome the uneven light distribution. In the light-emitting device, an optical lens with an indentation on its outer surface is disposed on a light source. The light source may be a LED, a LED chip, or other light-emitting elements. The optical lens can change the light intensity distribution (light shape) emitted from the light source to achieve uniform light output. More specifically, the indentation of the optical lens can reflect and/or refract the light emitted from the light source, thus effectively weakening the light intensity at the center. Moreover, a light-shielding material can be disposed in the indentation to further weaken the light intensity at the center, thereby further enhancing light uniformity. When the light-emitting device of the present disclosure is applied to a backlight module, the light-emitting device can simultaneously meet the requirements of providing uniform light and reducing the thickness of the module. Since the light source can be encapsulated by the optical lens, the light-emitting device of the present disclosure can be used in micro-LED packaging and the mini-LED packaging. Moreover, the manufacturing method of the light-emitting device has a simple process, which is conducive to reducing manufacturing costs. Next, the present disclosure describes a method of manufacturing a light-emitting device according to various embodiments of the present disclosure and then describes the light-emitting devices according to various embodiments of the present disclosure.

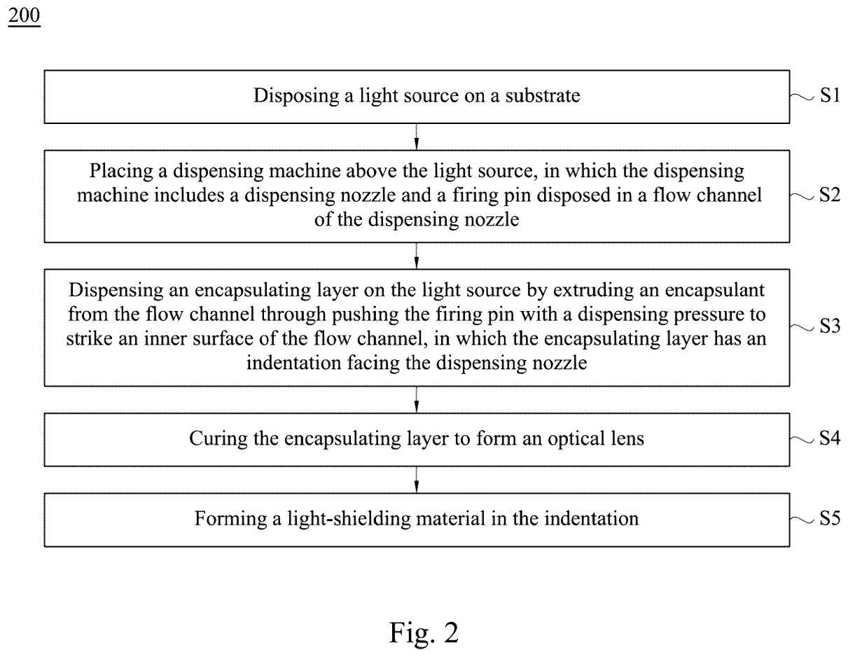

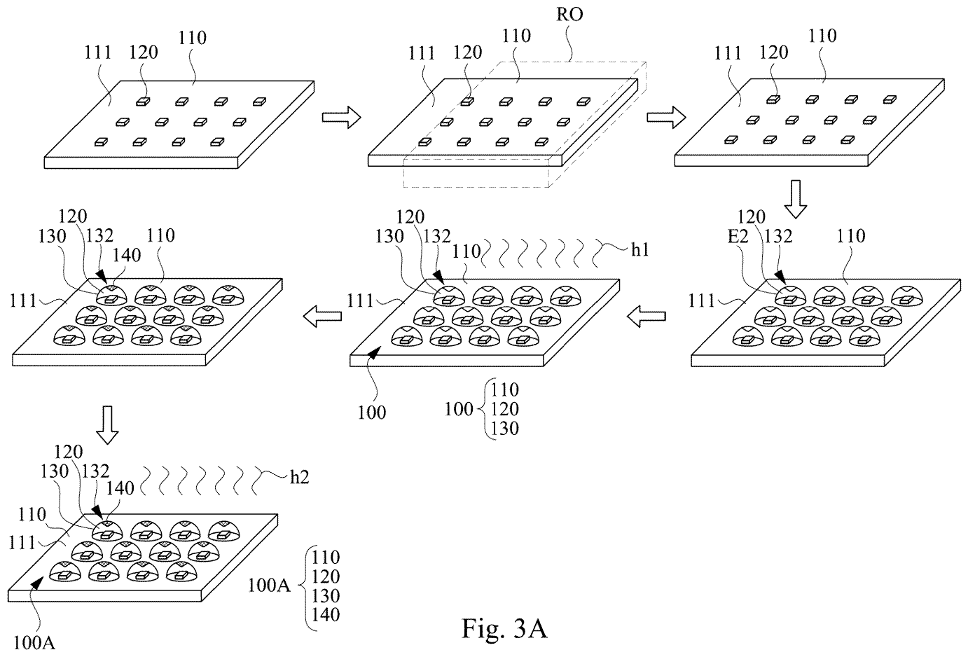

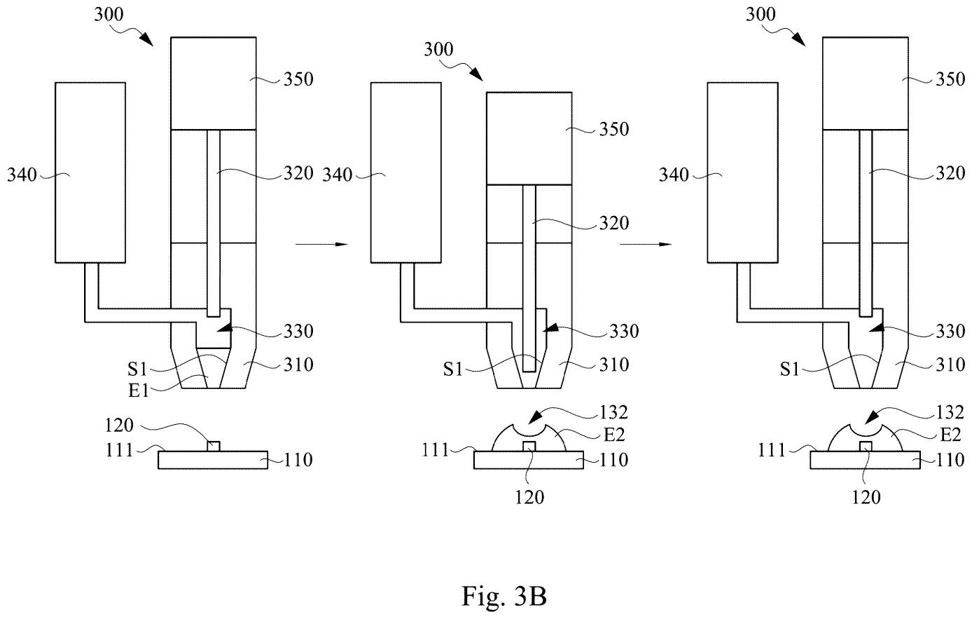

Please refer to FIG. 2 and FIG. 3A. FIG. 2 is a flowchart of a method 200 of manufacturing a light-emitting device according to various embodiments of the present disclosure. The method 200 includes operation S1, operation S2, operation S3, operation S4, and operation S5. FIG. 3A shows schematic views illustrating intermediate stages of manufacturing light-emitting devices according to various embodiments of the present disclosure. The method 200 of the present disclosure has a simple process, so the manufacturing cost can be reduced. Although a series of operations or steps are used below to describe the method disclosed herein, an order of these operations or steps should not be construed as a limitation to the present disclosure. For example, some operations or steps may be performed in a different order, and/or other steps may be performed at the same time. In addition, it is not necessary to perform all of the operations, steps, and/or features shown to achieve the embodiments of the present disclosure. In addition, each operation or step described herein may contain several sub-steps or actions.

Reference is made to FIG. 2 and FIG. 3A. FIG. 3A shows a process of manufacturing light-emitting devices. The amount of the light-emitting devices is not limited by FIG. 3A and can be arbitrarily adapted according to design requirement. For clarity, the manufacturing method of a single light-emitting device will be described below. In operation S1, a light source 120 is disposed on a substrate 110. In some embodiments, the substrate 110 is a printed circuit board (PCB), but is not limited thereto. In some embodiments, the light source 120 is a micro-LED, a micro-LED chip, a mini-LED, a mini-LED chip, a LED (having a size greater than that of the micro-LED and the mini-LED), a LED chip, or combinations therefore, but is not limited thereto. For example, the light source 120 is a chip scale package (CSP) LED. In some embodiments, as shown in FIG. 3A, disposing the light source 120 on the substrate 110 includes printing a solder paste (not shown) on the main surface 111 of the substrate 110, mounting the light source 120 on the solder paste by surface-mount technology (SMT), welding the light source 120 and the solder paste by reflow soldering in a reflow oven RO, and taking the substrate 110 attached with the light source 120 out of the reflow oven RO. In some embodiments, after taking the substrate 110 attached with the light source 120 out of the reflow oven RO, a reflective sheet is directly adhered on the upper surface of the light source 120.

Attention is now invited to FIG. 2, FIG. 3A, and FIG. 3B. FIG. 3B shows schematic cross-sectional views illustrating intermediate stages of forming an encapsulating layer E2 on the light source 120 by a dispensing machine 300 according to various embodiments of the present disclosure. The dispensing machine 300 can also be referred to as a dispenser. In operation S2, the dispensing machine 300 is placed above the light source 120, in which the dispensing machine 300 includes a dispensing nozzle 310 and a firing pin 320 disposed in a flow channel 330 of the dispensing nozzle 310. The dispensing machine 300 also includes a storage tank 340 for providing an encapsulant to the flow channel 330 and a driver 350 for driving the firing pin 320. In some embodiments, the dispensing machine 300 is an automated robot dispenser equipped with a firing pin.

Please refer to FIG. 2, FIG. 3A, and FIG. 3B. In operation S3, as shown in FIG. 3B, an encapsulating layer E2 is dispensed on the light source 120 by extruding an encapsulant E1 from the flow channel 330 through pushing the firing pin 320 with a dispensing pressure to strike an inner surface S1 of the flow channel 330, in which the encapsulating layer E2 has an indentation 132 facing the dispensing nozzle 310. As shown in FIG. 3A and FIG. 3B, the encapsulating layer E2 covers the light source 120. The indentation 132 is naturally formed during the dispensing process, which means forming the encapsulating layer E2 and forming the indentation 132 can be completed simultaneously. The shape of the indentation 132 can be adapted by dispensing parameters. The indentation 132 may also be referred as a concave part or a dent.

As shown in FIG. 3B, the firing pin 320 is driven by the driver 350. More specifically, the firing pin 320 can be pushed downward by the driver 350 to strike the inner surface S1 of the flow channel 330 and then be pulled upward. In some embodiments, the encapsulant E1 has a viscosity between 0.2 mPa·s and 100000 mPa·s, such as 0.2, 0.5, 1, 5, 10, 50, 100, 500, 1000, 2000, 3000, 4000, 5000, 6000, 7000, 8000, 9000, 10000, 20000, 30000, 40000, 50000, 60000, 70000, 80000, 90000, or 100000 mPa-s. When the viscosity of the encapsulant E1 falls within the above range, the encapsulant E1 can easily flow out from the dispensing nozzle 310 to form the encapsulating layer E2 with the indentation 132. In some embodiments, the encapsulant E1 includes silicone, epoxy, poly(methyl methacrylate), thixotropic gel, or combinations thereof. In some embodiments, a time for the firing pin 320 striking the inner surface S1 is 0.01 ms to 500 ms, and the dispensing pressure is 1 bar to 10 bar. For example, the time is 0.01, 0.05, 0.1, 0.5, 1, 5, 10, 20, 30, 40, 50, 60, 70, 80, 90, 100, 200, 300, 400, or 500 ms. For example, the dispensing pressure is 1, 2, 3, 4, 5, 6, 7, 8, 9, or 10 bar. When the strike time and/or the dispensing pressure fall within the above range, the encapsulant E1 can easily flow out from the dispensing nozzle 310 to form the encapsulating layer E2 with the indentation 132. The height and the diameter of the encapsulating layer E2 and the depth and the diameter of the indentation 132 can be adapted by the above dispensing parameters (the encapsulant viscosity, the strike time, and/or dispensing pressure).

As shown in FIG. 2 and FIG. 3A, in operation S4, the encapsulating layer E2 is cured to form an optical lens 130, thereby forming a light-emitting device 100. The light-emitting device 100 includes a portion of the substrate 110, the light source 120, and the optical lens 130 covering the light source 120 as shown in FIG. 3A. In some embodiments, curing the encapsulating layer E2 is performed by a heating operation h1. For example, the temperature of the heating operation h1 may between 40 ° C and 130 ° C., such as 40, 50, 60, 70, 80, 90, 100, 110, 120, or 130 ° C In some embodiments, curing the encapsulating layer E2 includes the following operations. The encapsulating layer E2 is heated under a first temperature from 40 ° C to 60 ° C., such as 40, 45, 50, 55, or 60 ° C., thereby preheating the encapsulating layer E2. Next, the encapsulating layer E2 is heated under a second temperature from 80 ° C to 100 ° C., such as 80, 85, 90, 95, or 100 ° C., thereby solidifying the encapsulating layer E2. Subsequently, the encapsulating layer E2 is heated at a third temperature from 110 ° C to 130 ° C., such as 110, 115, 120, 125, or 130 ° C., such as 40, 50, 60, 70, 80, 90, 100, 110, 120, or 130 ° C., thereby hardening the encapsulating layer E2. The above heating operations can effectively cure the encapsulating layer E2 and make it less prone to deformation during the curing process. By the simple process shown in FIG. 3A, an integrated structure including the optical lens 130 and the light source 120 can be easily formed.

Please still refer to FIG. 2 and FIG. 3A. In operation S5, a light-shielding material 140 is formed in the indentation 132, thereby forming a light-emitting device 100A. The light-emitting device 100A includes a portion of the substrate 110, the light source 120, the optical lens 130 covering the light source 120, and the light-shielding material 140 in the indentation 132 as shown in FIG. 3A. In other some embodiments, operation S5 is omitted. In some embodiments, forming the light-shielding material 140 in the indentation 132 includes the following operations. An encapsulant material and a pigment powder (the light-shielding material 140) are dispensed in the indentation 132 by, for example, a dispensing machine, in which the pigment powder is dispersed in the encapsulant material. In some embodiments, the refractive index of the encapsulant material is between 1.41 and 1.6. The pigment powder can have any color and includes, for example, white powder, black powder, grey powder, red powder, orange powder, yellow powder, green powder, blue powder, purple powder, pink powder, brown powder, or combinations thereof. For example, the pigment powder includes TiO₂ powder, SiO₂ powder, or combinations thereof. The white powder can have a better effect of weakening the central light because of its better light reflection property. For example, the central light intensity of the light-emitting device 100A can be less than 80%.

The encapsulant material and the pigment powder are cured by a heating operation h2. For example, the temperature of the heating operation h2 may between 40 ° C and 130 ° C., such as 40, 50, 60, 70, 80, 90, 100, 110, 120, or 130 ° C In some embodiments, curing the encapsulant material and the pigment powder includes the following operations. The encapsulant material and the pigment powder are heated under a first temperature from 40 ° C to 60 ° C., such as 40, 45, 50, 55, or 60 ° C., thereby preheating the encapsulant material and the pigment powder. Next, the encapsulant material and the pigment powder are heated under a second temperature from 80 ° C and 100 ° C., such as 80, 85, 90, 95, or 100 ° C., thereby solidifying the encapsulant material and the pigment powder. Subsequently, the encapsulant material and the pigment powder are heated under a third temperature from 110 ° C and 130 ° C., such as 110, 115, 120, 125, or 130 ° C., thereby hardening the encapsulant material and the pigment powder. The above heating operations can effectively cure the encapsulant material and the pigment powder and make them less prone to deformation during the curing process.

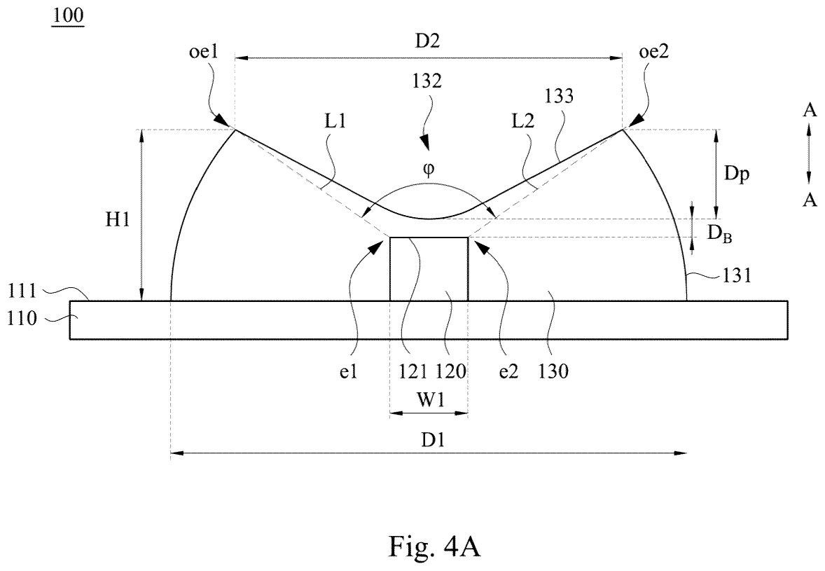

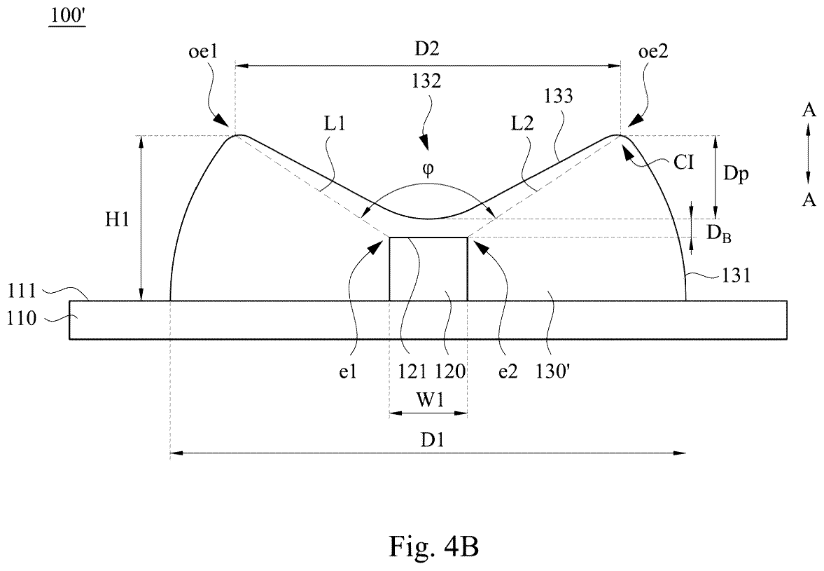

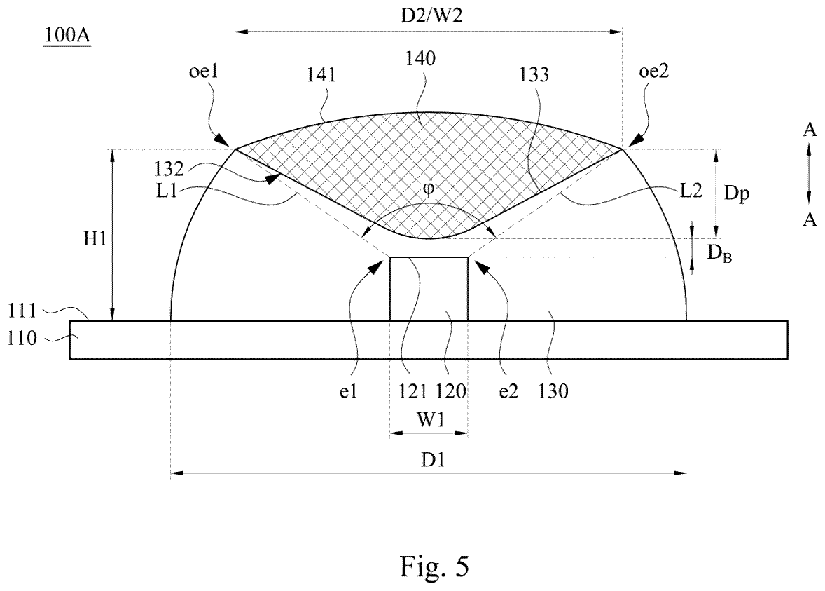

The light-emitting device 100 and the light-emitting device 100A will be further described in FIG. 4A and FIG. 5. FIG. 4B shows another light-emitting device similar to the light-emitting device 100. FIG. 4A, FIG. 4B, and FIG. 5 are respectively schematic cross-sectional views of light-emitting devices according to various embodiments of the present disclosure.

As shown in FIG. 4A, the light-emitting device 100 includes the substrate 110, the light source 120, and the optical lens 130. The substrate 110 has the main surface 111, i.e., the top surface of the substrate 110 shown in FIG. 4A. The light source 120 is disposed on the main surface 111 and has a light-emitting surface 121 away from the main surface 111. The optical lens 130 is disposed on the main surface 111 and covers the light source 120, in which the optical lens 130 has an outer surface 131 away from the light source 120 and an indentation 132 located on the outer surface 131 and above the light-emitting surface 121. In some embodiments, the optical lens 130 includes silicone, epoxy, poly(methyl methacrylate), thixotropic gel, or combinations thereof. Along the direction A perpendicular to the main surface 111 of the substrate 110, the indentation 132 is disposed in correspondence with the light-emitting surface 121. Therefore, the vertical projection of the indentation 132 on the main surface 111 and the vertical projection of the light source 120 on the main surface 111 overlap. As shown in FIG. 4A, in some embodiments, the outer surface 131 has a convex curved surface, and the indentation 132 has a concave curved surface.

Please still refer to FIG. 4A. In some embodiments, a distance DB between a bottom of the indentation 132 and the light-emitting surface 121 is from 0 mm to 19.9 mm, such as 0, 0.05, 0.1, 0.5, 1, 2, 4, 6, 8, 10, 12, 14, 16, 18, or 19.9 mm. In some embodiments, the indentation 132 has a depth Dp from 0.05 mm to 19.9 mm, such as 0.05, 0.1, 0.5, 1, 2, 4, 6, 8, 10, 12, 14, 16, 18, or 19.9 mm. When the distance DB and/or the depth Dp fall within the above range, the light emitted from the central part of the optical lens 130 can be effectively weakened. In some embodiments, a height H1 of the optical lens 130 is from 0.1 mm to 20 mm, such as 0.1, 0.5, 1, 2, 4, 6, 8, 10, 12, 14, 16, 18, or 20 mm.

As show in FIG. 4A, in some embodiments, in a cross-section of the light-emitting device 100, the light-emitting surface 121 has a first endpoint e1 and a second endpoint e2, the first endpoint e1 and a first opening edge oe1 of the indentation 132 define a first virtual line L1, the second endpoint e2 and a second opening edge oe2 of the indentation 132 define a second virtual line L2. The first opening edge oe1 and the second opening edge oe2 are at the highest point of the optical lens 130. An angle φ between the first virtual line L1 and the second virtual line L2 is greater than 0 degree and less than or equal to 160 degrees, such as 0, 20, 40, 60, 80, 100, 120, 140, or 160 degrees. When the angle q falls within the above range, the light emitted from the central part of the optical lens 130 can be effectively weakened.

Please still refer to FIG. 4A. The optical lens 130 has a first diameter D1, and an opening of the indentation 132 has a second diameter D2. In some embodiments, a ratio of first diameter D1 to the second diameter D2 is 1.3:1 to 2:1, such as 1.3:1, 1.4:1, 1.5:1, 1.6:1, 1.7:1, 1.8:1, 1.9:1, or 2:1. When the ratio falls within the above range, the light emitted from the central part of the optical lens 130 can be effectively weakened. For example, the central light intensity of the light-emitting device 100 can be less than 80%. In some embodiments, the first diameter D1 is between 0.5 mm and 10 mm, such as 0.5, 1, 2, 3, 4, 5, 6, 7, 8, 9, or 10 mm. In some embodiments, the second diameter D2 is between 0.1 mm and 8 mm, such as 0.1, 0.5, 1, 2, 3, 4, 5, 6, 7, or 8 mm.

Please still refer to FIG. 4A. The light source 120 has a width W1. In some embodiments, the second diameter D2 of the opening of the indentation 132 is greater than or equal to the width W1 of the light source 120. In some embodiments, the second diameter D2 of the opening of the indentation 132 is less than the width W1 of the light source 120. All of the above embodiments can increase light distribution uniformity. When the second diameter D2 is greater than or equal to the width W1, the light distribution uniformity is better.

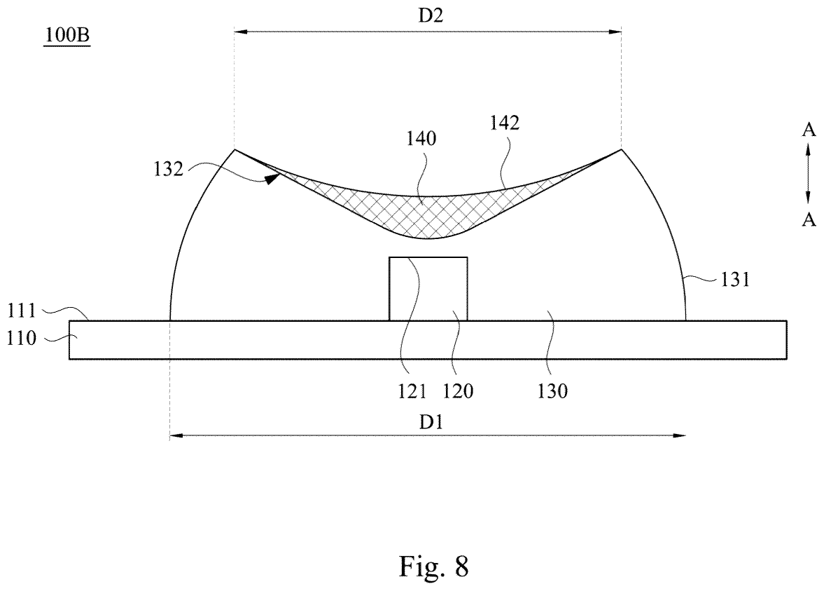

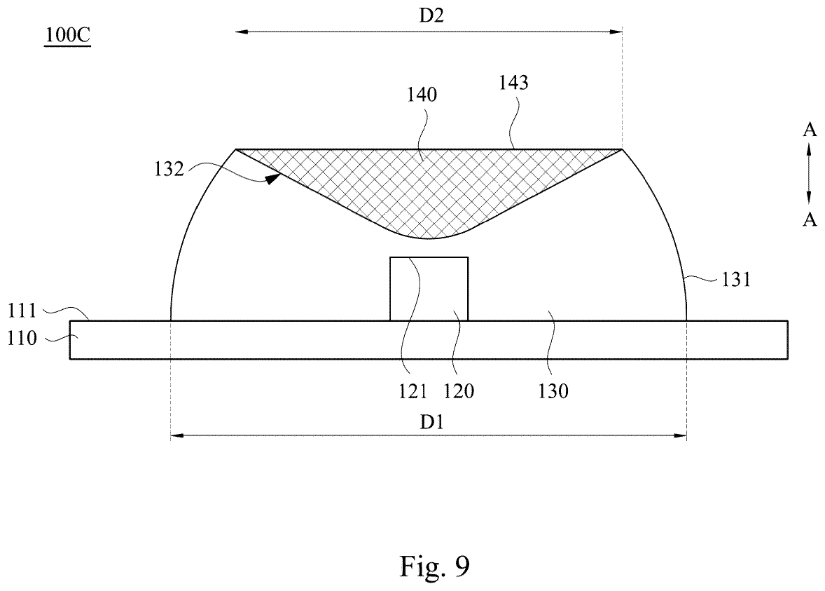

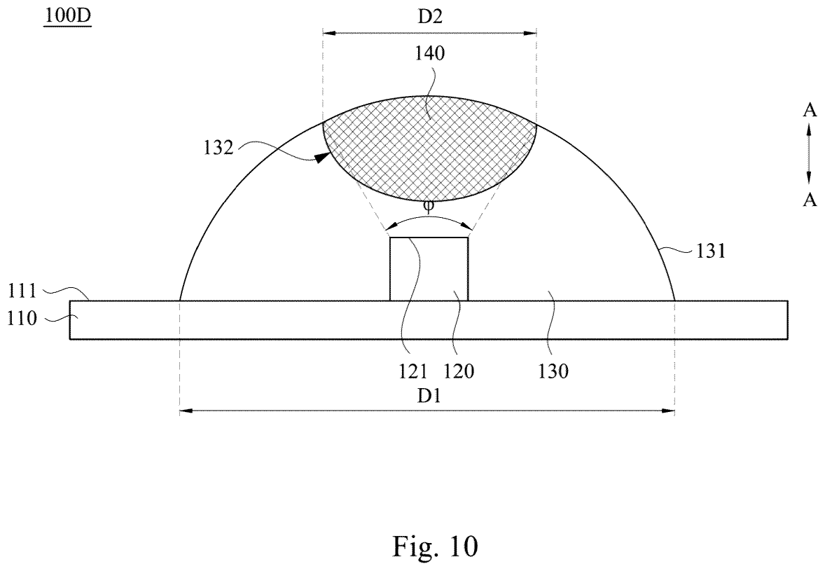

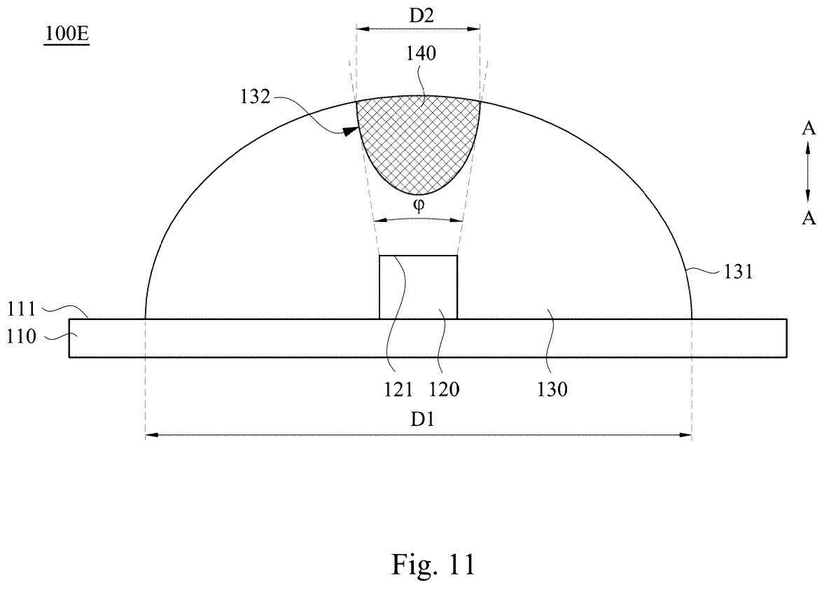

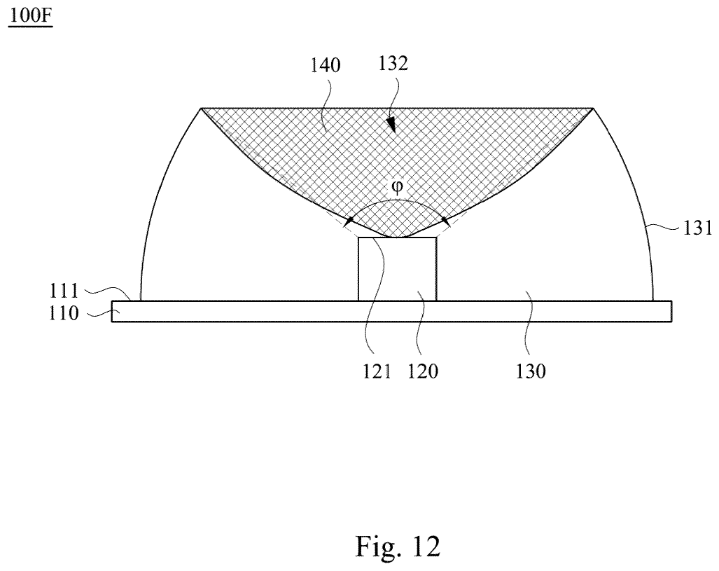

Although the optical lens 130 shown in FIG. 4A has two obvious turning points between the outer surface 131 of the optical lens 130 and the inner surface 133 of the indentation 132, the present disclosure is not limited thereto. Furthermore, the shape of the indentation 132 is not limited by FIG. 4A, and any shape of the indentation 132 can weaken the central light intensity. Attention is now invited to FIG. 4B. The difference between the light-emitting device 100′ of FIG. 4B and the light-emitting device 100 of FIG. 4A is that the outer surface 131 of the optical lens 130′ and the inner surface 133 of the indentation 132 are smoothly connected without any obvious turning points. In other words, the outer surface 131 of the optical lens 130′ and the inner surface 133 of the indentation 132 form a smoothly curved interface CI. By the previous mentioned dispensing parameters, the process shown in FIG. 2, FIG. 3A, and FIG. 3B can also form the optical lens 130′ shown in FIG. 4B. In practical applications, both the light-emitting device 100′ and the light-emitting device 100 can provide uniform light output. It is noted that the optical lenses 130 shown in the following FIG. 5, FIG. 8, FIG. 9, FIG. 10, FIG. 11, FIG. 12, and FIG. 13, also can be modified to have the smoothly curved interface CI shown in FIG. 4B.

Attention is now invited to FIG. 5. The difference between the light-emitting device 100A of FIG. 5 and the light-emitting device 100 of FIG. 1 is that the light-emitting device 100A further includes a light-shielding material 140 in the indentation 132. In some embodiments, a distance DB between the light-shielding material 140 and the light-emitting surface 121 is from 0 mm to 19.9 mm, such as 0, 0.05, 0.1, 0.5, 1, 2, 4, 6, 8, 10, 12, 14, 16, 18, or 19.9 mm. In some embodiments, the indentation 132 has a depth Dp from 0.05 mm to 19.9 mm, such as 0.05, 0.1, 0.5, 1, 2, 4, 6, 8, 10, 12, 14, 16, 18, or 19.9 mm. When the distance DB and/or the depth Dp fall within the above range, the light emitted from the central part of the optical lens 130 can be effectively weakened. In some embodiments, the light-shielding material 140 fills the indentation 132 and protrudes out of the indentation 132 as shown in FIG. 5. In some embodiments, the light-shielding material 140 has a convex curved upper surface 141, but the present disclosure is not limited thereto. In some embodiments, the light-shielding material 140 has a transmittance of less than 80% for light with a wavelength of 360 nm to 1000 nm, such as 360, 400, 500, 600, 700, 800, 900, or 1000 nm. The transmittance can be less than or equal to 75, 70, 65, 60, 55, 50, 45, 40, 35, 30, 25, or 20%. In some embodiments, the light-shielding material 140 includes an encapsulant and a pigment powder dispersed in the encapsulant. In some embodiments, the encapsulant of the light-shielding material 140 includes silicone, epoxy, poly(methyl methacrylate), thixotropic gel, or combinations thereof.

Please refer to FIG. 4A and FIG. 5. In the light-emitting device 100, the optical lens 130 can change the light intensity distribution (light shape) emitted from the light source 120 to achieve uniform light output. The indentation 132 of the optical lens 130 can reflect and/or refract the light emitted from the light source 120, thus effectively weakening the light intensity at the center. Furthermore, in the light-emitting device 100A, both the indentation 132 of the optical lens 130 and the light-shielding material 140 can reflect and/or refract the light emitted from the light source 120, thus further effectively weakening the light intensity at the center. The advantages of the light-emitting device 100′ in FIG. 4B are similar to that of the light-emitting device 100.

Please still refer to FIG. 5. The light-shielding material 140 has a maximum width W2. In some embodiments, the maximum width W2 of the light-shielding material 140 is greater than or equal to the width W1 of the light source 120. In some embodiments, the maximum width W2 of the light-shielding material 140 is less than the width W1 of the light source 120. All of the above embodiments can increase light distribution uniformity. When the maximum width W2 is greater than or equal to the width W1, the light distribution uniformity is better.

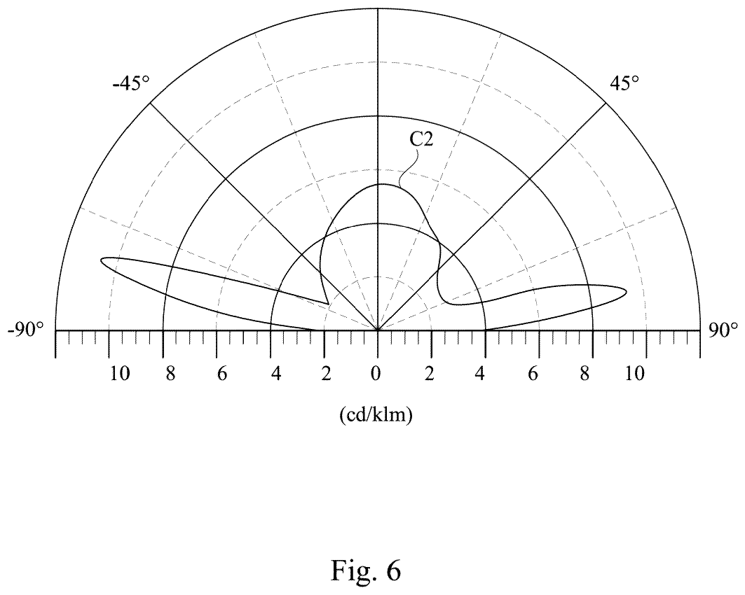

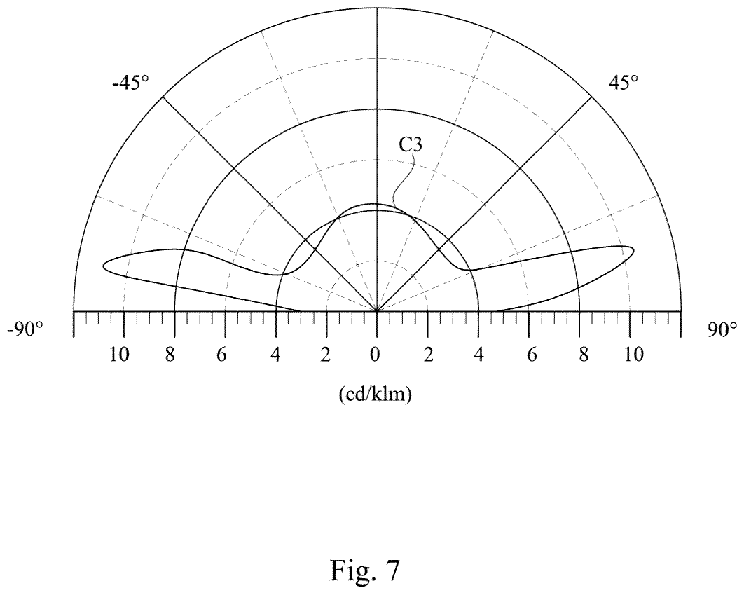

Next, FIG. 6 shows a luminous intensity distribution curve C2 generated by the light-emitting device 100 of FIG. 4A between the luminous angle of −90 degrees and 90 degrees. FIG. 7 shows a luminous intensity distribution curve C3 generated by the light-emitting device 100A of FIG. 5 between the luminous angle of −90 degrees and 90 degrees.

It should be noted that the luminous intensity distribution curves of FIG. 6 and FIG. 7 are obtained by the same light sources 120 and the same optical lenses 130. The light sources 120 are blue flip chip (FC) LED chips (6V) with green and red phosphors and with a size of 18 mil×18 mil. The first diameter D1 of the optical lenses 130 is 5.5 mm, and the height H1 of the optical lenses 130 is 1.2 mm. As can be seen from FIG. 6, the luminous intensity (central light intensity) at the luminous angle of 0 degree is about 50%, the luminous intensity at the luminous angle of 90 degrees is about 93%, the view angle along X axis is 156 degrees, and the view angle along Y axis is 156 degrees. As can be seen from FIG. 7, the luminous intensity (central light intensity) at the luminous angle of 0 degree is about 35%, the luminous intensity at the luminous angle of 90 degrees is about 44%, the view angle along X axis is 171 degrees, and the view angle along Y axis is 165 degrees. Therefore, it can be known that both the light-emitting device 100 and the light-emitting device 100A can weaken the central light intensity. The light-emitting device 100A can have a greater view angle and/or a beam angle. Since the light-emitting device 100A includes the light-shielding material 140, it can further effectively weaken the central light intensity.

In some embodiments, the light-emitting device 100 has a view angle greater than or equal to 150 degrees. In some embodiments, the light-emitting device 100A has a view angle greater than or equal to 150 degrees. When N1 light-emitting devices are arranged in a backlight module, and the lenses of these light-emitting devices do not have indentations, more light-emitting devices need to be arranged to meet the requirements of the backlight module. When N2 light-emitting devices 100 or N2 light-emitting devices 100A are arranged in a backlight module, and the lenses of the light-emitting devices 100 or the light-emitting devices 100A have indentations 132 and therefore have larger view angles, fewer light-emitting devices 100 or fewer light-emitting devices 100A can be arranged to meet the requirements of the backlight module. That means the number N2 is less than the number N1. Therefore, the light-emitting devices 100 and the light-emitting devices 100A of the present disclose can reduce manufacturing cost of the backlight module.

Further, one hundred known light-emitting devices and one hundred light-emitting devices 100A shown in FIG. 5 are respectively disposed on PCBs having a size of 100 mm×100 mm. The known light-emitting devices and the light-emitting devices 100A respectively include blue FC LED chips (6V) with green and red phosphors and with a size of 18 mil×18 mil. Diffusers are respectively disposed above the known light-emitting devices and the light-emitting devices 100A. In the known light-emitting devices, each blue FC LED chip is covered by a plano-convex lens with a diameter of 5.5 mm and a height of 1.2 mm. In the light-emitting devices 100A, each blue FC LED chip is covered by the optical lens 130 with the indentation 132 (the second diameter D2 is 5.5 mm, and the height H1 is 1.2 mm). Moreover, the light-emitting devices 100A respectively have white light-shielding materials 140. The pitches of the known light-emitting devices are 7.5 mm×7.5 mm, and the pitches of the light-emitting devices 100A are 7.5 mm×7.5 mm. The distance between the top surface of the PCB and the bottom surface of the diffuser is a vertical distance (H), and the distance between adjacent light-emitting devices is a horizontal distance (P). In the structure including the known light-emitting devices, the optical distance (OD) is about 7.0 mm to about 8.0 mm (H/P ratio is about 1.0). In the structure including the light-emitting devices 100A, the OD is about 3.5 mm to about 4.0 mm (H/P ratio is about 0.5). Therefore, it can be seen that when the light-emitting device 100A is applied in a backlight module, the OD can be reduced, thereby reducing the thickness of the backlight module.

FIG. 8, FIG. 9, FIG. 10, FIG. 11, and FIG. 12, are respectively schematic cross-sectional views of light-emitting devices according to various embodiments of the present disclosure.

FIG. 8 shows a light-emitting device 100B, and the difference between the light-emitting device 100B and the light-emitting device 100A of FIG. 5 is that the light-shielding material 140 of light-emitting device 100B has a concave curved upper surface 142. Moreover, a part of the indentation 132 is not filled with the light-shielding material 140, and the light-shielding material 140 does not protrude from the indentation 132. In some other embodiments, a part of the indentation 132 is not filled with the light-shielding material 140, and the light-shielding material 140 protrudes from the indentation 132 (not shown).

FIG. 9 shows a light-emitting device 100C, and the difference between the light-emitting device 100C and the light-emitting device 100A of FIG. 5 is that the light-shielding material 140 of light-emitting device 100C has a substantially planar upper surface 143. In some embodiments, the indentation 132 is filled with the light-shielding material 140 as shown in FIG. 9. In some other embodiments, the light-shielding material 140 is below the highest position of the optical lens 130 (not shown).

The shapes of the optical lens 130 and the indentation 132 are not limited to FIG. 4A, FIG. 4B, FIG. 5, FIG. 6, FIG. 7, FIG. 8, and FIG. 9. FIG. 10 shows a light-emitting device 100D, in which the second diameter D2 of the indentation 132 of FIG. 10 is less than the second diameter D2 of the indentation 132 of FIG. 5. Therefore, the light-shielding material 140 of FIG. 10 is narrower than the light-shielding material 140 of FIG. 5. FIG. 11 shows a light-emitting device 100E, in which the second diameter D2 of the indentation 132 of FIG. 11 is less than the second diameter D2 of the indentation 132 of FIG. 10. Therefore, the light-shielding material 140 of FIG. 11 is narrower than the light-shielding material 140 of FIG. 10. The second diameter D2 and the width of the light-shielding material 140 can be adapted according to different requirements for light distribution uniformity.

FIG. 12 shows a light-emitting device 100F. The light-shielding material 140 is in direct contact with the light-emitting surface 121 of the light source 120. In other words, the distance between the light-shielding material 140 and the light-emitting surface 121 is 0 μm. Further, the distance between the bottom of the indentation 132 and the light-emitting surface 121 of the light source 120 is 0 μm.

FIG. 13 is a schematic cross-sectional view of a light-emitting device 100G according to various embodiments of the present disclosure. The light-emitting device 100G includes a substrate 110, light sources 120, optical lenses 130, and at least one light-shielding wall 150. The substrate 110 has a main surface 111. Each light source 120 is disposed on the main surface 111 and has a light-emitting surface 121 away from the main surface 111. Each optical lens 130 is disposed on the main surface 111 and covers the light source 120 and has an outer surface 131 away from the light source 120 and an indentation 132 located on the outer surface 131 and above the light-emitting surface 121. FIG. 13 shows the light-shielding walls 150. Each light-shielding wall 150 is disposed on the main surface 111 and near the optical lens 130. The light-shielding walls 150 can separate the light sources 120 from each other to prevent the light interference or the light-overflow. In some embodiments, the optical lens 130 has the height H1 (a first height), the light-shielding wall 150 has the height H2 (a second height), and the height H2 is less than or equal to two times the height H1, thus achieving a better effect of preventing the light interference or the light-overflow. In some embodiments, the light-shielding walls 150 are white. The light-shielding walls 150 can have any color, such as white, black, grey, red, orange, yellow, green, blue, purple, pink, brown, or combinations thereof. When the light-shielding walls 150 have white color, they can have a better effect of preventing the light interference.

The following describes the features of the present disclosure more specifically with reference to Experimental Examples 1-2. Although the following experimental examples are described, the materials, their amounts and ratios, processing details, processing procedures, etc., may be appropriately varied without exceeding the scope of the present disclosure. Accordingly, the present disclosure should not be interpreted restrictively by the experimental examples described below.

### EXPERIMENTAL EXAMPLE 1: MEASUREMENT OF LIGHT-EMITTING DEVICES

In Example 1, multiple light-emitting devices 100A as shown in FIG. 5 were respectively disposed on a PCB. CSP LEDs were used as the light sources 120, and the light-shielding materials 140 were white. A diffuser was disposed above the light-emitting devices 100A. The distance between the top surface of the PCB and the bottom surface of the diffuser is a vertical distance (H), and the distance between adjacent light-emitting devices 100A is a horizontal distance (P). The structural parameters of the optical lenses 130, other structural parameters, and the measurement results are listed in the following Table 1. Examples 2-3 are similar to Example 1, and the parameters of Examples 2-3 are listed in the following Table 1.

TABLE 1

| Example | 1 | 2 | 3 |
|---|---|---|---|
| First diameter D1 (mm) | 5.436 | 4.706 | 3.754 |
| Second diameter D2 (mm) | 2.904 | 2.722 | 2.114 |
| Ratio of D1 to D2 | 1.87:1 | 1.73:1 | 1.78:1 |
| Height H1 (mm) | 2.5 | 1.8 | 2.1 |
| Aspect ratio of optical lens | 2.17:1 | 2.61:1 | 2.21:1 |
| Depth Dp (μm) | 371 | 340 | 331 |
| Distance D_{B} (μm) | 229 | 260 | 247 |
| Luminous efficiency (Lm/W) | 75.27 | 86.02 | 93.19 |
| Optical Distance OD (mm) | 3.6 | 1.8 | 2.3 |
| H/P Ratio | 0.497 | 0.248 | 0.317 |

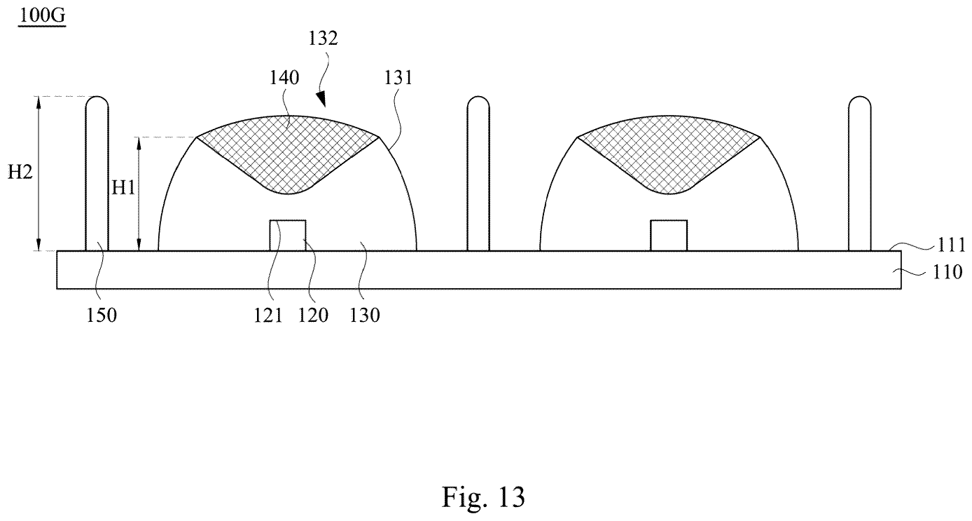

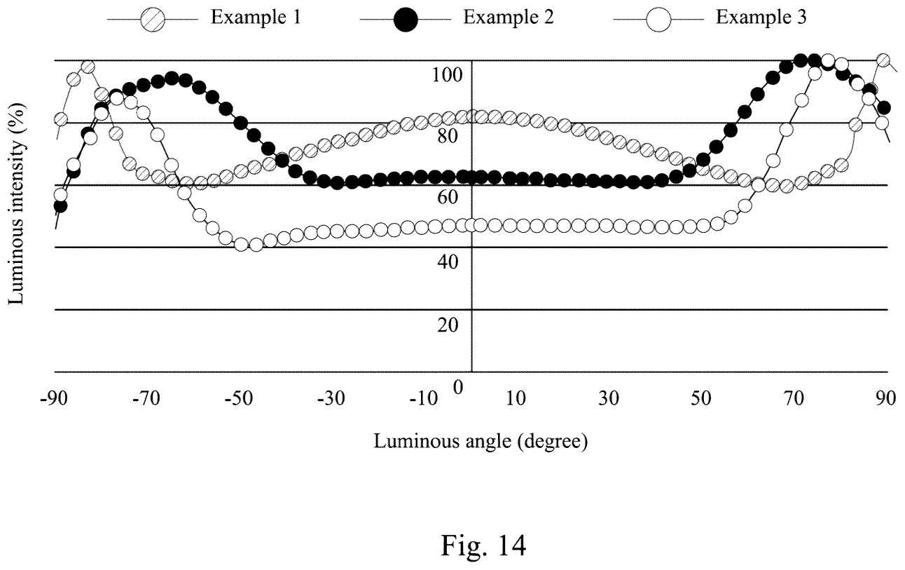

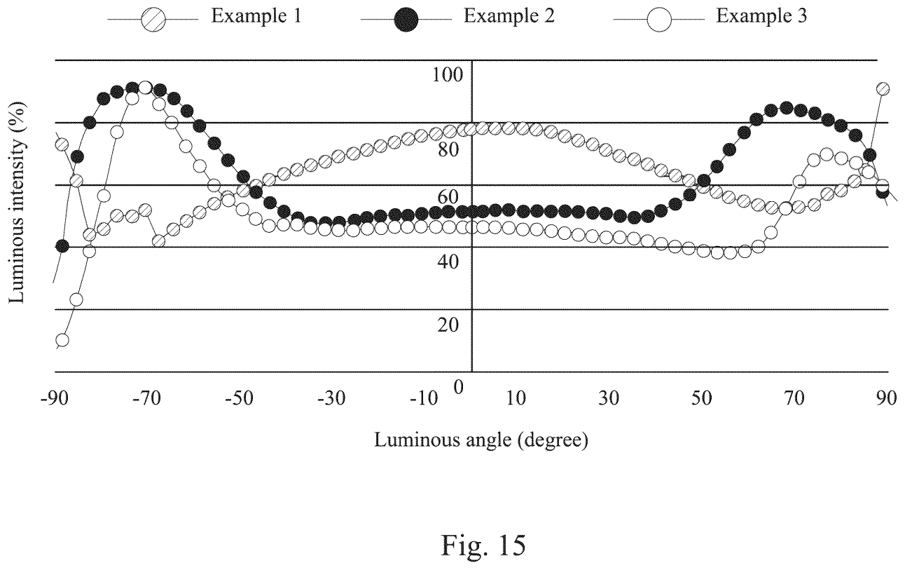

FIG. 14 illustrates luminous intensity change curves generated by the light-emitting devices 100A of Examples 1-3 between the luminous angle of −90 degrees and 90 degrees at the longitudinal plane of 0 degree. FIG. 15 illustrates luminous intensity change curves generated by the light-emitting devices 100A of Examples 1-3 between the luminous angle of −90 degrees and 90 degrees at the longitudinal plane of 90 degrees. It can be seen from Table 1, FIG. 14, and FIG. 15 that, because of the larger first diameter D1 and the second diameter D2, the light-emitting devices 100A of Example 1 has the greater central light intensity. Therefore, Examples 2-3 are more advantageous in weakening the central light intensity. Moreover, because of the smaller first diameter D1 and the second diameter D2, the H/P Ratio of Example 3 is greater than that of Examples 1-2. Therefore, Example 2 can simultaneously have a good effect of reducing the central light intensity and the smaller H/P ratio.

### EXPERIMENTAL EXAMPLE 2: MANUFACTURE OF LIGHT-EMITTING DEVICES

In Examples 4-9, multiple light-emitting devices 100A as shown in FIG. 5 were respectively used. CSP LEDs were used as the light sources 120, and the light-shielding materials 140 were white. The structural parameters of the optical lenses 130 and the measurement results are listed in the following Table 2. When the ratio of D1 to D2 falls within 1.3 to 2, the light emitted from the central part of the optical lens 130 can be effectively weakened.

TABLE 2

| Example | 4 | 5 | 6 | 7 | 8 | 9 |
|---|---|---|---|---|---|---|
| First diameter D1 (mm) | 4.924 | 5.044 | 4.814 | 4.912 | 5.044 | 5.086 |
| Second diameter D2 | 3.728 | 2.924 | 2.408 | 2.898 | 2.924 | 2.798 |
| (mm) | | | | | | |
| Ratio of D1 to D2 | 1.32:1 | 1.73:1 | 2:1 | 1.69:1 | 1.73:1 | 1.82:1 |
| Height H1 (μm) | 1256 | 1231 | 1247 | 1223 | 1238 | 1227 |
| Depth Dp (μm) | 370 | 361 | 385 | 518 | 361 | 195 |
| Distance D_{B} (μm) | 374 | 385 | 356 | 70 | 450 | 630 |
| Luminous efficiency | 77.06 | 89.64 | 91.2 | 85.51 | 89.64 | 86.23 |
| (Lm/W) | | | | | | |

In summary, the present disclosure provides a light-emitting device and a manufacturing method thereof. The light-emitting device includes an optical lens with an indentation that can change the light intensity distribution (light shape) emitted from a light source to achieve uniform light output. The indentation can reflect and/or refract the light emitted from the light source, thus effectively weakening the light intensity at the center to reduce the luminous directivity. A light-shielding material can be disposed in the indentation to further weaken the light intensity at the center, thereby further enhancing light uniformity. When the light-emitting device is disposed in a backlight module, the optical distance (OD) of the backlight module can be reduced, thereby reducing the total thickness of the module, and the backlight module can have an uniform light intensity distribution.

Although the present disclosure has been described in considerable detail with reference to certain embodiments, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover the modifications and variations of the present disclosure falling within the scope of the appended claims.

What is claimed is:

1. A light-emitting device comprising:
a substrate having a main surface;
a light source disposed on the main surface and having a light-emitting surface away from the main surface; and
an optical lens disposed on the main surface and covering the light source, wherein the optical lens has an outer surface away from the light source and an indentation located on the outer surface and above the light-emitting surface.

2. The light-emitting device of claim 1, wherein the outer surface has a convex curved surface, and the indentation has a concave curved surface.

3. The light-emitting device of claim 1, wherein a distance between a bottom of the indentation and the light-emitting surface is from 0 mm to 19.9 mm.

4. The light-emitting device of claim 1, wherein the optical lens has a first diameter, an opening of the indentation has a second diameter, and a ratio of first diameter to the second diameter is 1.3:1 to 2:1.

5. The light-emitting device of claim 1, wherein the optical lens comprises silicone, epoxy, poly(methyl methacrylate), thixotropic gel, or combinations thereof.

6. The light-emitting device of claim 1, wherein the indentation has a depth from 0.05 mm to 19.9 mm.

7. The light-emitting device of claim 1, wherein, in a cross-section of the light-emitting device, the light-emitting surface has a first endpoint and a second endpoint, the first endpoint and a first opening edge of the indentation define a first virtual line, the second endpoint and a second opening edge of the indentation define a second virtual line, and an angle between the first virtual line and the second virtual line is greater than 0 degree and less than or equal to 160 degrees.

8. The light-emitting device of claim 1, further comprising at least one light-shielding wall disposed on the main surface and near the optical lens, wherein the optical lens has a first height, the light-shielding wall has a second height, and the second height is less than or equal to two times the first height.

9. The light-emitting device of claim 1, further comprising a light-shielding material in the indentation.

10. The light-emitting device of claim 9, wherein the light-shielding material has a transmittance of less than 80% for light with a wavelength of 360 nm to 1000 nm.

11. The light-emitting device of claim 9, wherein the light-shielding material fills the indentation and protrudes out of the indentation.

12. The light-emitting device of claim 9, wherein the light-shielding material comprises an encapsulant and a pigment powder dispersed in the encapsulant.

13. A method of manufacturing a light-emitting device, the method comprising:
disposing a light source on a substrate;
placing a dispensing machine above the light source, wherein the dispensing machine comprises a dispensing nozzle and a firing pin disposed in a flow channel of the dispensing nozzle;
dispensing an encapsulating layer on the light source by extruding an encapsulant from the flow channel through pushing the firing pin with a dispensing pressure to strike an inner surface of the flow channel, wherein the encapsulating layer has an indentation facing the dispensing nozzle; and
curing the encapsulating layer to form an optical lens.

14. The method of claim 13, wherein the encapsulant has a viscosity between 0.2 mPa·s and 100000 mPa·s.

15. The method of claim 13, wherein a time for the firing pin striking the inner surface is 0.01 ms to 500 ms, and the dispensing pressure is 1 bar to 10 bar.

16. The method of claim 13, wherein curing the encapsulating layer comprises:
heating the encapsulating layer under a first temperature from 40 ° C to 60 ° C;
heating the encapsulating layer under a second temperature from 80 ° C to 100 ° C; and
heating the encapsulating layer at a third temperature from 110 ° C to 130 ° C.

17. The method of claim 13, wherein the encapsulant comprises silicone, epoxy, poly(methyl methacrylate), thixotropic gel, or combinations thereof.

18. The method of claim 13, further comprising forming a light-shielding material in the indentation.

19. The method of claim 18, wherein the light-shielding material fills the indentation and protrudes out of the indentation.

20. The method of claim 18, wherein forming the light-shielding material in the indentation comprises:
dispensing an encapsulant material and a pigment powder in the indentation, wherein the pigment powder is dispersed in the encapsulant material;
heating the encapsulant material and the pigment powder under a first temperature from 40 ° C to 60 ° C;
heating the encapsulant material and the pigment powder under a second temperature from 80 ° C and 100 ° C; and
heating the encapsulant material and the pigment powder under a third temperature from 110 ° C and 130 ° C.
